(19) United States
(12) Patent Application Publication
(10) Pub. No.: US 2002/0053917 A1
(43) Pub. Date: May 9, 2002

(54) Probe structure and method for manufacturing the same

(75) Inventors: Michinobu Tanioka, Tokyo (JP); Takahiro Kimura, Tokyo (JP)

Correspondence Address: SUGHRUE, MION, ZINN, MACPEAK & SEAS, 2100 Pennsylvania Avenue, N.W., Washington, DC, 20037-3202, US

(73) Assignee: NEC CORPORATION

(21) Appl. No.: 09/984,515

(22) Filed: Oct. 30, 2001

(30) Foreign Application Priority Data
Oct. 30, 2000 (JP) 2000-330523

(51) Int. Cl. G01R 31/02

(52) U.S. Cl. 324/754

(57) ABSTRACT

A probe structure according to the invention includes a base substrate 7, a plurality of probe pins 3 provided at predetermined respective positions on a top side of the base substrate, a plurality of through electrodes 5 respectively corresponding to a plurality of electrodes K1 of a testing board K, and rewiring layers 4 for electrically interconnecting each of the probe pins 3 and each of the through electrodes 5 individually on the top side of the base substrate, in which the probe pins 3 are each composed of a silicon-made core and a conductive film 32 formed thereon and the through electrodes 5 each pass through the base substrate 7 from one side to the other thereof and have a pitch thereof set larger than a pitch of the probe pins.

### BACKGROUND OF THE INVENTION

1. Field of the Invention

The invention relates to a semiconductor LSI (Large Scale Integration) or a probe which comes in contact with an electrode of a bare LSI (bare chip) and, more particularly to, a probe suitable for testing of a bare chip with a small inter-electrode pitch and a method for manufacturing the same.

2. Description of the Related Art

Conventionally, in testing of a semiconductor device, a probe structure has been contacted with an external terminal electrode of the test-subject semiconductor device to give electric contact between this device and a testing board. The probe employed in the testing has been made of a metal needle, a metal pin, a membrane sheet with metal bump, a plated silicon whisker, etc.

An example of the probe made of a metal needle is described in U.S. Pat. No. 5,969,533, an example made of a membrane sheet with a metal bump is described in Japan Patent Application Laid-Open No. Hei 5-226430, and an example made of a silicon whisker is described in Japan Patent Application Laid-Open No. Hei 11-190748. These are detailed below.

(1) “PROBE CARD AND LSI TEST METHOD USING PROBE CARD” of U.S. Pat. No. 5,969,533 discloses a pitch narrowing construction using a probe obtained by processing a needle made of a metal such as tungsten. In such a configuration as shown in FIG. 9, four stages are stacked one on another each of which includes a plurality of probe needles 119 having a root diameter of 190 μm each and being separated from each other by a blocking plate 118, so that an inter-probe-tip pitch can be reduced down to 50 μm for improving the position accuracy.

(2) “PROBE CARD STRUCTURE AND METHOD FOR MANUFACTURING THE SAME” of Japan Patent Application Laid-Open No. Hei 5-226430, “BUMP-CONTACT-LOADED THIN-FILM PROBE BUFFER SYSTEM” of Japan Patent Application Laid-Open No. Hei 5-243344, and “PROBE CARD” of WO98/58266 disclose therein a probe structure of such an approach that uses a contact sheet having a metal bump at a position opposite an external electrode C1 of a semiconductor device C. As its representative is described in FIG. 10 the “PROBE CARD STRUCTURE AND METHOD FOR MANUFACTURING THE SAME” of Japan Patent Application Laid-Open No. Hei 5-226430 as follows. In the disclosure, in a probe card structure, desired testing circuit pattern and electrode lead 121 are formed on one side of a flexible insulator film 120, which electrode lead has a metal bump 122 formed at a tip thereof (i.e., a position facing the external electrode of the semiconductor device) . This metal bump comes in contact with the external terminal electrode C1 of the semiconductor device C.

(3) “PROBE CARD” of Japan Patent Application Laid-Open No. Hei 11-190748 discloses a probe construction using a probe pin obtained by plating a grown mono-crystal silicon needle. As shown in FIG. 11, in such a construction, to lead a wiring out of a contactor board 128 on which a probe pin 127 is formed, an FPC129 is used for electric connection to a testing board 130.

The following will describe the problems of the above-mentioned prior arts.

In a probe construction according to the first prior art example U.S. Pat. No. 5,969,533, metal needles and blocking plates are combined to constitute a four-staged stack of probe, having problems: [1] it is very difficult to process these needles and blocking plates and assemble them for electric connection to the testing board, thus increasing the costs; and [2] even with the four-staged stack configuration, the inter-probe-tip pitch is still 50 μm, and further narrowing of the pitch is difficult due to a problem of the rigidity of the metal needle.

In a probe construction according to the second prior art example Japan Patent Application Laid-Open No. Hei 5-226430, a metal bump is used for contacting with the external electrode of a semiconductor device and is held at least at a certain level in height so that it may not come in contact with a circuit surface of the semiconductor device when it comes in contact therewith, so that the inter-metal-bump pitch must be at least 60 μm or so, thus resulting in difficulty in further narrowing.

In a probe construction according to the third prior art example Japan Patent Application Laid-Open No. Hei 11-190748, a pin obtained by plating a grown mono-crystal silicon needle is used for contact with the external electrode C1 of the semiconductor device C to horizontally lead out a wiring using a flexible board and a connector. In this case, the pin material is made of plated silicon, so that this prior art example has a disadvantage that the pin may be damaged easily when the semiconductor device C is pressed in to an inadequate extent. Even if the press-in extent is within an allowable range, the external terminals of the semiconductor device are irregular in height, so that to maintain effective contact with these external terminals, the device is always pressed in to some extent, thus leading to a problem that its service life is shortened due to deterioration of the probe.

Further, in every one of the structures of those prior art probes, the probes are all arranged at the center of a holder for holding them in such a configuration that wirings for electrically connecting the probes to electrodes of a testing board are spread and formed in a radial manner to the periphery of the holder or even beyond it to the outside. Accordingly, these wirings extend at least to the periphery of the holder to increase the wiring resistance and, in some cases, cause a difference in wiring length depending on the arrangement of the probes, thus leading to a possible disadvantage of a signal delay at the time of high-speed operations.

Also, in the card type probe structure, in which the wirings are similarly formed in a spread radial manner to the periphery of the card, there is a need to arrange electrodes side by side at that periphery for electric connection with the electrodes on the testing board. To set the size of those electrodes in such a range as not to increase the manufacturing costs generally (i.e., a range not dependent on the micro-patterning technologies used in the production of the semiconductor devices), it is necessary to increase the inter-electrode pitch to thereby increase the size of the card itself, thus resulting in an disadvantage of elongation of the wiring.

### SUMMARY OF THE INVENTION

In view of the above, it is an object of the invention to provide a probe structure and method for manufacturing the same which solves the above-mentioned problems and is suitable for testing a semiconductor device with a narrowed inter-electrode pitch.

Present invention is a probe structure for electrically contacting a semiconductor device and a testing board with each other, comprising: a base substrate used with one side thereof as faced to the semiconductor device and the other side thereof as faced to the testing board; a plurality of probe pins provided on the one side of the base substrate at positions corresponding to a plurality of external terminals of the semiconductor device respectively; a plurality of through electrodes individually provided corresponding to a plurality of electrodes of the testing board; and rewiring layers for individually connecting the probe pins and the through electrodes respectively on the one side of the base substrate.

And the probe pins are each comprised of a silicon-made core and a conductive film formed thereon; and the through electrodes each pass through the base substrate from one side to the other thereof and have a pitch as exposed on the other side of the base substrate set larger than a pitch of the probe pins.

Above configuration is used to electrically interconnecting the testing board and each of a great number of semiconductor devices yet to be cut out from the wafer for individually checking them for acceptance/rejection. In this testing, they are judged as to whether they are accepted or rejected by observing, with a tester on the side of the testing board, their output signal corresponding to a signal input to them from the testing board according to a testing program thereof.

In this configuration, through electrodes are aligned with testing electrodes and then electrically connected therewith, while on the other hand the tips of the probe pins are allowed to come in contact with the external terminals of a semiconductor device. In this state, between the electrodes of the testing board and the external terminals of the semiconductor device, a signal is transmitted and received via the probe pin, the rewiring layer, and the through electrode. This enables to judge the quality of the semiconductor.

Moreover, present invention further comprising an elastic contactor provided on the other side of the base substrate, for providing individual conduction between each of the through electrodes and each of the electrodes of the testing board.

In above configuration. there is often a difference in height between each external terminal of the semiconductor device and each electrode of the testing board, so that to avoid a non-contact state in such a case, at the time of testing, the semiconductor device is pressed against the testing board with a probe structure as sandwiched therebetween. In this configuration, with the structure as pressed, the contactor is elastically deformed and yet attempts to provide conduction between each through electrode and each electrode of the testing board, so that it is possible to relax deformation due to pressing of the other components of the probe structure, especially the probe pin while maintaining good contact.

Moreover, present invention having the probe structure, wherein the contactor is made of an elastic sheet material in which a great number of metal fine wirings are buried therethrough.

The invention attempts to relax the pressing force by use of deformation of the sheet material and yet provide conduction between each of the through electrodes of the metal wirings and each of the electrodes of the testing board.

Moreover, present invention having the probe structure, wherein the metal fine wirings are each buried perpendicular to a surface of the sheet material.

In the invention, each metal fine wiring is buried perpendicularly, so that to electrically connect each of the through electrode to each of the electrode of the testing board, the through electrode only needs to be positioned vertically above the electrode of the testing board.

Moreover, in present invention, wherein the metal fine wirings are somewhat inclined with respect to the surface of the sheet material.

In the invention, each metal fine wiring is buried as somewhat inclined, to electrically connect each of the through electrodes to each of the electrodes of the testing board, the through electrode only needs to be positioned as shifted from above the electrode of the testing board vertically taking into inclination.

Moreover, in present invention, wherein the contactor is individually provided at an end of each of the through electrodes exposed from the other side of the base substrate and made of a metal wiring material which is elastic and also which is so shaped as to be flexed arbitrarily.

In the invention, each of the through electrodes are electrically connected to each of the electrodes of the testing board via the metal wiring material. After connection, each metal wiring material flexes to thereby relax the pressing force and yet allow transmission of a signal through this metal wiring material.

Moreover, present invention having the probe structure , wherein the contactor is individually provided at an end of each of the through electrodes exposed from the other side of the base substrate and made of a wiring material which is comprised of an elastic core material and a reinforcing material for coating the core material to add elasticity and also which is so shaped as to be flexed arbitrarily.

The invention, each of the through electrodes are electrically connected to each of the electrodes of the testing board via the wiring material. After connection, a reinforcing material with which each wiring material is coated flexes to thereby relax the pressing force and yet allow transmission of a signal through the wiring material.

Moreover, in present invention, the base substrate has a multi-layer construction; and the through electrodes are each comprised of a conductive through electrode component formed through each layer of the base substrate and a wiring layer intervening between the layers for providing conduction between the through electrode components.

In the invention, a signal passes through the layers of a multi-layer structured base substrate via through electrode components, which are electrically interconnected through a wiring layer, so that the signal is transmitted and received as passing through the base substrate in its thickness direction.

Moreover, present invention is a method for manufacturing a probe structure for electrically contacting a semiconductor device and a testing board, comprising the steps of: forming a plurality of through electrodes in a predetermined base substrate from one side to the other thereof as arranged corresponding to electrodes of the testing board; forming a rewiring layer which is provided on one side of the base substrate and also which provides individual conduction to each of the through electrodes from each position corresponding to each of a plurality of external terminals of the semiconductor device; and forming a probe pin which is provided on the one side of the base substrate and also which contacts each of the external terminal to each position corresponding to each of the plurality of external terminals of the semiconductor device.

And the step of forming the through electrodes includes a step of forming a plurality of holes as arranged corresponding to the electrodes of the testing board of the base substrate to fill the holes with a conductive material; and the step of forming the probe pin includes a step of growing a silicon-made whisker at each position corresponding to each of the plurality of external terminals of the semiconductor device to then form a conductive film on each of the silicon-made whiskers.

The invention attempts to solve the above-mentioned problems using those configurations.

### BRIEF DESCRIPTION OF THE DRAWINGS

FIG. 1 is a cross-sectional view for showing a first embodiment of the invention;

FIG. 2 is an expanded cross-sectional view for showing surroundings of a probe pin of FIG. 1;

FIG. 3 is a plan view for showing a probe structure of FIG. 1;

FIGS. 4A-4I are illustrations for showing steps of manufacturing the probe structure of FIG. 1 in this order;

FIG. 5 is a cross-sectional view for showing the probe structure provided with a different anisotropic conductive sheet;

FIG. 6 is a cross-sectional view for showing the probe structure provided with a different contactor;

FIG. 7 is a cross-sectional view for showing a second embodiment of the invention;

FIG. 8 is a cross-sectional view for showing surroundings of a through electrode of FIG. 7;

FIG. 9 is a perspective view for showing a first prior art example;

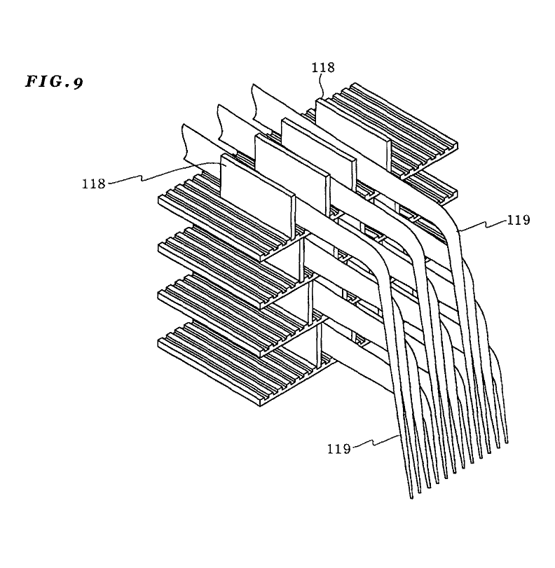

FIG. 10 is a cross-sectional view for showing a second prior art example; and

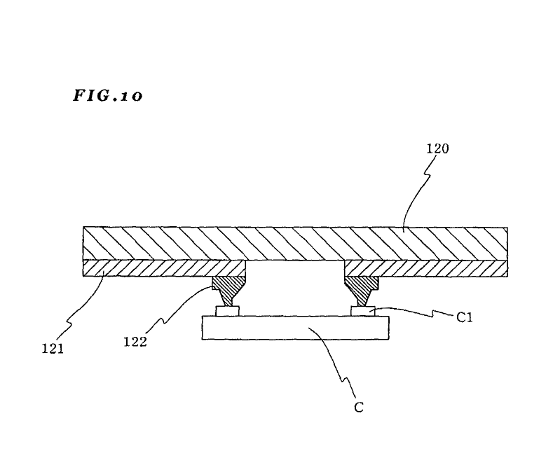

FIG. 11 is a front view for showing a third prior art example.

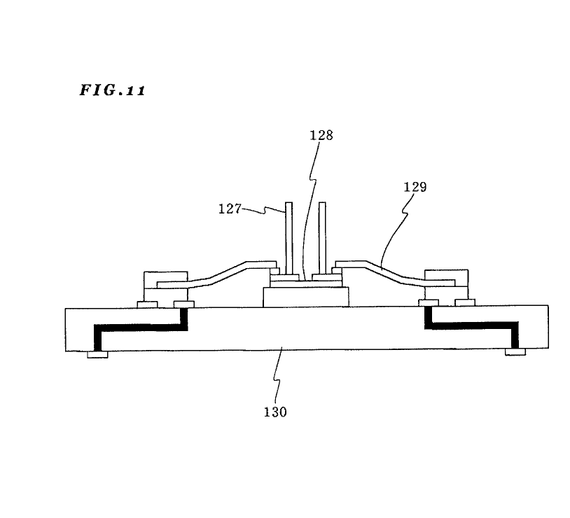

### DESCRIPTION OF THE PREFERRED EMBODIMENTS

The following will describe embodiments of a present invention with reference to the drawings.

First Embodiment

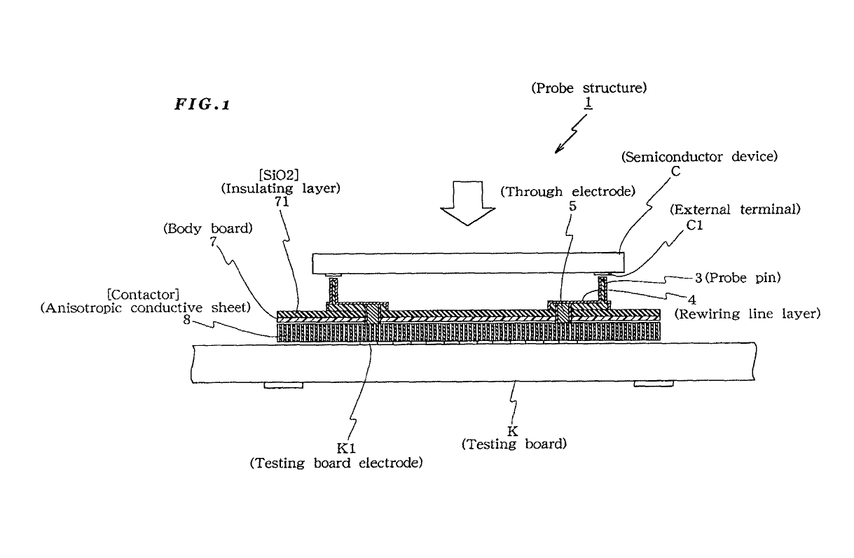

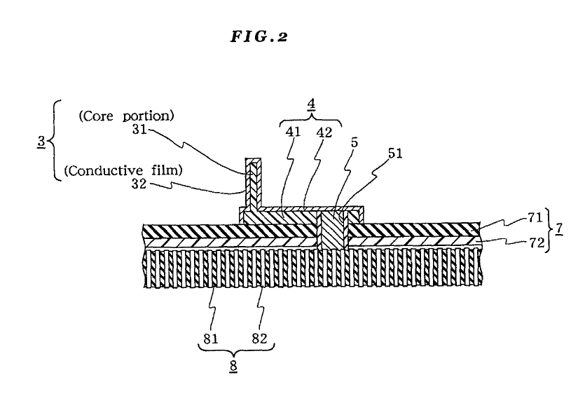

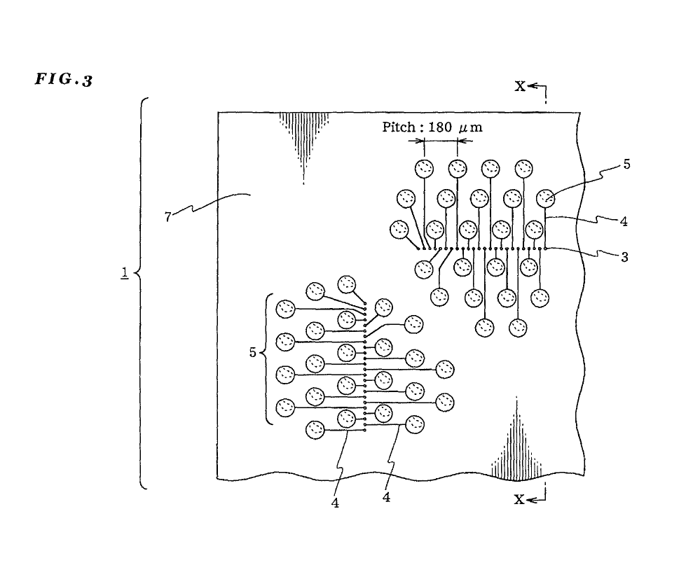

The following will describe a first embodiment of the invention. This embodiment gives a probe structure 1 for providing electric contact between a testing board K and a semiconductor device C to be tested. FIG. 1 is a cross-sectional view of the probe structure 1, FIG. 2 is an expanded cross-sectional view of an important part of the probe structure 1, and FIG. 3 is a partial plan view of the probe structure 1.

As shown in FIG. 1, the probe structure 1 includes a base substrate 7 which is used with its top side as faced to a semiconductor device C and its back side as faced to a testing board K, a plurality of probe pins 3 provided at positions respectively corresponding to a plurality of external terminals C1 of the semiconductor device C to be tested on the top side of the base substrate 7, a plurality of through electrodes 5 provided individually corresponding to a plurality of electrodes K1 of the testing board K, a rewiring layer 4 formed on the top side of the base substrate 7 for electrically interconnecting the probe pins 3 and the through electrodes 5 individually, and an anisotropic conductive sheet 8 which is positioned on the side of the back side of the base substrate 7, which is elastic, and which serves as a contactor for individually contacting each through electrode 5 to each electrode K1 of the testing board K. Those components are detailed below.

(Base substrate)

The base substrate 7 is comprised of a silicon layer 72 made of Si and an insulating layer 71 which is made of SiO₂ and formed on the top side of the silicon layer 72. This insulating layer 71 is formed to insulate the rewiring layers 4 from each other and also each of them and the base substrate 7 from each other.

(Probe pins)

As shown in FIG. 2, each of the probe pins 3 is obtained by growing mono-crystal silicon to provide a core portion 31, conducting electroless nickel-plating and electrolytic gold plating on its outer periphery to provide a conductive film 32, and then palladium-plating its tip portion to obtain certain hardness. Since the probe pin 3 is thus formed to be a round rod provided perpendicular on the top side of the base substrate 7, when it come sin contact with the external terminal electrode C1 of the semiconductor device C, it has flexure to some extent, which can be combined with elastic deformation of the later-described anisotropic conductive sheet 8 to absorb fluctuations in thickness of both the semiconductor device C and the external terminal C1. Also, the probe pins 3 are arranged as many as the same number and at the same pitch of the plurality of the external terminals C1 of the semiconductor device C.

(Through electrodes)

Each of the through electrodes 5 is formed by dry-etching the base substrate 7, which is an SOI (Silicon On Insulator), and provided perpendicular to the plate face of the base substrate 7. The upper end of the through electrode 5 is exposed on the top side of the base substrate 7 and the lower end thereof protrudes from the back side of the base substrate 7. Also, the through electrode 5 is covered side-wise by a side-wall insulator film 51 for insulating its side from the base substrate 7.

(Rewiring layers)

Each of the rewiring layers 4 is formed on the top side of the base substrate 7 and comprised of a silicon layer 41 formed as a core in such a direction as to electrically interconnect the probe pin 3 and the through electrode 5 and a plated layer 42 formed thereon by plating.

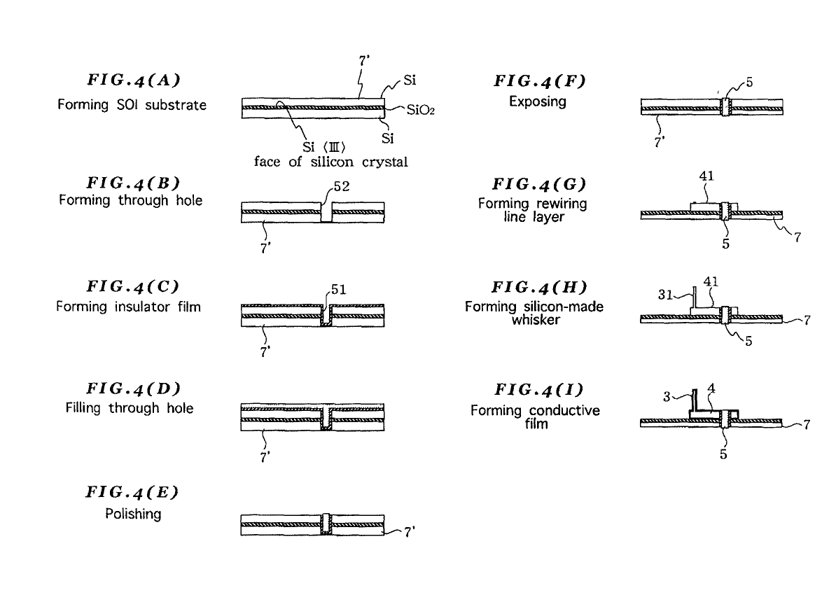

This silicon layer 41 is actually formed by etching the silicon layer (see FIG. 4A) formed uniformly on the top side of the insulating layer 71 of the base substrate 7 according to a lead-out electrode pattern (see FIG. 3) for electrically connect the probe pin 3 via the through electrode 5 to the electrode K1 of the testing board K. The above-mentioned core portion 31 of the probe pin 3 is formed on this silicon layer 41. Accordingly, by simultaneously plating the surface of the silicon layer 41 uniformly together with the core portion 31, the plated layer 42 and the conductive film 32 of the probe pin 3 are formed.

Since the probe pins 3 are arranged depending on the arrangement of the external terminals C3 of the semiconductor device C to be tested, the pitch of the probe pins 3 is also limited in a certain range. The arrangement and the pitch of the through electrodes 5 are, however, free of such a limitation as that of the probe pins 3 because the through electrodes 5 are electrically connected to the probe pins through the above-mentioned rewiring layer 4. That is, if the pitch of the electrode pads K1 of the testing board K is larger than the pitch of the external terminal electrodes C1 of the semiconductor device C, a pattern of a wiring led out to expand the latter pitch can be formed by this rewiring layer 4.

(Anisotropic conductive sheet)

The anisotropic conductive sheet 8 is comprised of a sheet material 81 made of silicone rubber and a great number of metal fine wirings 82 buried throughout the sheet material 81 perpendicular (to its surface). The sheet material 81 is set at almost the same size as the plate surface of the base substrate 7. The upper and lower ends of each of the metal fine wirings 82 somewhat protrude from the top and back sides of the sheet material 81 respectively. Also, the diameter of each metal fine wiring 82 is set smaller than at least the outer diameter of the through electrode 5 and the pitch at which the metal fine wirings 82 are arranged is set smaller than that of the through electrodes 5 Accordingly, no matter where the through electrodes 5 are arranged on the plate surface of the base substrate 7, at least some of the metal fine wirings 82 come in contact with the lower end of the through electrode 5, thus enabling electrically connecting with the electrode K1 of the testing board K.

This anisotropic conductive sheet 8 is held with a pin, screw, adhesive, etc. not shown on the base substrate 7, for example, at its outer periphery where the through electrode 5 is not disposed.

The anisotropic conductive sheet 8 is itself deformed due to its own elasticity to thereby relax the occurrence of deformation of the probe pin 3 when the semiconductor device C is pressed against the probe pin 3 for contact therebetween in testing. This can effectively avoid deterioration of the probe pin due to damage and deformation thereof.

Also, since the anisotropic conductive sheet can be deformed, it can effectively accommodate irregularities in height of the electrodes K1 which are caused by flexure of the testing board K, thus properly interconnecting the through electrodes 5 and the electrodes K1 correspondingly. Therefore, it is possible to mitigate the force with which the semiconductor device C is pressed against the probe pin 3, thus effectively avoiding the damage and deterioration f the probe pins 3.

(Description of arrangement of the probe pins, through electrodes, and rewiring layers)

FIG. 3 shows one example of arranging the through electrodes 5 with an expanded pitch of the probe pins 3. This arrangement example corresponds only to a case where the external terminals C1 are arranged with a 30-μm pitch along each side of a square-shaped semiconductor device C, only one corner of which is shown in the figure.

As described above, the probe pins 3 are arranged in a row along each side of this square similar to the external terminals C1 of the semiconductor device C, with a pitch set at 30 μm. On each of both sides of this row of the probe pins 3 are arranged three rows of the through electrodes 5 in parallel with the row of the probe pins 3. Those through electrodes 5 are connected to the corresponding probe pins 3 through the rewiring layers 4 respectively.

These rows of the through electrodes S are arranged with respectively offset distances with respect to the row of the probe pins 3. Accordingly, in each row, the adjacent through electrodes 5 have a pitch set at 180 μm. Although the pitch of the through electrode 5 should preferably be set small to downsize the probe structure 1, a smaller pitch of the through electrodes 5 means a smaller pitch of the electrode K1 of the testing board K. To thus excessively downsize the testing board K, it is necessary to employ the manufacturing technologies for the semiconductor device C (use of photo-resists, sputtering, plating, etc.), which is not desirable from the viewpoint of the productivity and production costs of the testing board K. Therefore, the above-mentioned inter-through-electrode 5 pitch value of 180 μm may be appropriate taking into account the trade-off between the downsizing of the probe structure 1 and the productivity of the testing board K.

Since the through electrode 5 is formed through the base substrate 7, it need not extend to the edge of the board in contrast to a prior art embodiment, thus increasing the degree of freedom in arrangement. Accordingly, this makes it possible to set the pitch of the through electrodes 5 at an appropriate value, not too large nor too small, thus downsizing the probe structure 1 to such an extent as not to decrease the productivity of the testing board K and also reducing the rewiring layers in size.

On the other hand, the probe pins 3 have the pitch thereof set at 30 μm, the height set at 500-800 μm, and the diameter at its top side portion set at 15 μm.

Also, the metal fine wiring 82 of the anisotropic conductive sheet 8 disposed on the back side of the base substrate 7 is made of such a material as tungsten, beryllium copper, etc., has a wiring diameter of 30 μm or less, has its outer periphery plated with gold, has its inter-fine-wire pitch set at 30-50 μm or so in both X- and Y-directions, and also has the thickness of the sheet material 81 set at 1 mm or less.

Although the positional relationship between the probe pins 3 and the corresponding through electrodes 5 is somewhat offset due to the above-mentioned wiring, such an extent of offset in distance is small enough to permit the pressing force on the semiconductor device C in testing to be effectively transmitted to the through electrodes 5 and also to effectively preserve contact between these through electrodes 5 and the anisotropic conductive sheet 8 and that between the anisotropic conductive sheet 8 and the electrodes K1 of the testing device K for testing.

(Manufacturing method)

The following will detail a method for manufacturing the above-mentioned probe structure 1 with reference to FIG. 4.

First, as shown in FIG. 4A, the SiO₂ film 71 serving as a passivation layer is formed by CVD (Chemical Vapor Deposition) to a thickness of 2 μm or so on the surface of the <111>face side ((111) is a Miller index) of a silicon wafer which provides a base for the SOI substrate 7, on which is in turn formed the Si layer which provides the core of the rewiring layer 4. Thus, a base substrate material 7′ is formed.

Next, as shown in FIG. 4B, a through hole 52 is formed in the base substrate material 7′ using such a processing technology as an RIE (Reactive Ion Etching) method, a laser method (KrF, THG-YAG, etc.), an EB (Electron Beam) method, etc. (note here that the through hole 52 is referred to as a through hole although it has a bottom until a step of FIG. 4F).

Next, to preserve insulation between the base substrate 7 and the through electrodes 5, an inorganic film is formed by CVD on the side wall of the through hole 52, on which wall is in turn formed a barrier metal layer made of Ti/W, Cr, etc. serving as the side-wall insulator film 51 (FIG. 4C) . Then, the through hole 52 is filled with metal such as Cu, Au, W, Mo, etc. using electrolytic or electroless plating (FIG. 4D) and then undergoes CMP (Chemical Mechanical Polishing) to remove excessive insulating layer and Cu layer formed on the top for flattening (FIG. 4E).

Also, the back side of the base substrate material 7′ is selectively etched similarly to permit the lower end of the through electrode 5 to protrude from the silicon substrate (FIG. 4F). On the flattened surface of the top side of the Si layer on the top side of the base substrate material 7′ is sputtered or evaporated a gold thin film, on which is in turn applied a photo-resist, which undergoes photolithographic processing to form a wiring pattern of the rewiring layer 4, thus forming the silicon layer 41, which serves as the core of the rewiring layer 4. Also, a gold bump is provided at a position on thus formed silicon layer 41 at which the probe pin 3 is to be disposed as provided (FIG. 4G).

This is heated to a temperature not lower than the melting point of a Si-Au alloy in a gas atmosphere containing a silicon compound such as SiH₄, SiCl₄, etc. to grow an acicular silicon crystal, thus forming the core portion 31 of the probe pin 3 (FIG. 4H) . This whisker growing method is disclosed as a publicly known technology. Then, to provide a uniform length of the silicon whiskers, their tips are trimmed by mechanical polishing.

Next, the core portion 31 of the probe pin 3 and the silicon layer 41 of the rewiring layer 4 are nickel-plated to a thickness of 0.1 μm or so by electroless plating and gold-plated to a thickness of 2 μm or so electrolytically to thereby form the conductive film 32 and the plated layer 42. With this, the probe pin 3 and the rewiring layer 4 are formed. Further, the lower end of the through electrodes 5 which protrudes from the back side of the base substrate 7 are plated with nickel and gold, while only on the upper end of the probe pin 3 is plated with palladium (FIG. 41).

Then, the anisotropic conductive sheet 8 is attached to the back side of the base substrate 7, thus manufacturing the probe structure 1.

(Miscellaneous)

Although in the cross-sectional view of the probe structure of FIG. 1 a pitch of the two probe pins 3 is shown narrower than that between the two through electrodes 5, the pitch referred to here indicates one between the probe pins 3 of the same row or the corresponding through electrodes 5. FIG. 1 shows a cross-sectional view of FIG. 3 as taken along line X-X, in which the probe pins belong to the different rows.

(Another example of anisotropic conductive sheet)

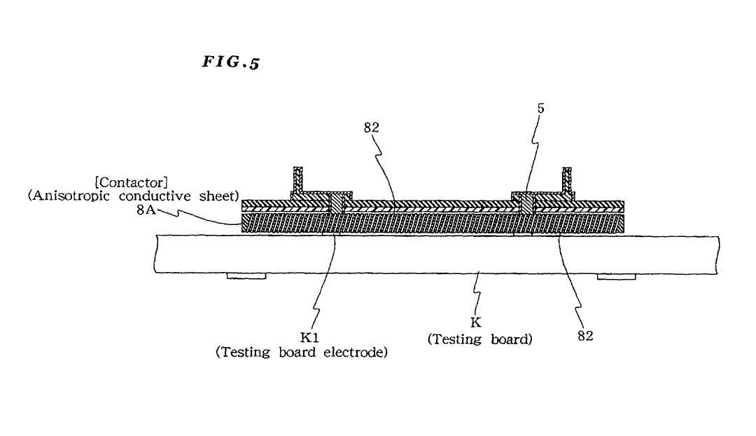

FIG. 5 shows a variant of the anisotropic conductive sheet 8. A new anisotropic conductive sheet 8A shown in the figure is comprised of the sheet material 81 and a great number of metal fire wirings 82 which are buried throughout the sheet material 81 as somewhat inclined with respect to perpendicularity. This sheet 8A is the same as the anisotropic conductive sheet 8 except this. Since the metal fine wirings 82A are thus inclined in this anisotropic conductive sheet 8A, the through electrodes 5 need to be arranged as offset with respect to the electrodes K1 of the testing board K by as much as that inclination, except which it has almost the same effects as the anisotropic conductive sheet 8.

(Another example of contactor)

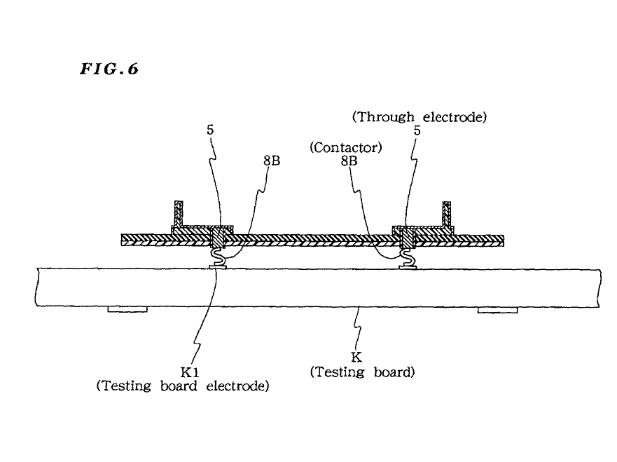

FIG. 6 shows an example where in place of the anisotropic conductive sheet 8, such a metal wiring material 8B is employed as the contactor that is individually provided to the lower end of each through electrode 5 exposed from the back side of the base substrate 7 and that has elasticity and also is so shaped as to be flexed arbitrarily. This metal wiring material 8B is given in a one-to-one relationship with the through electrode 5 and is comprised of a gold wiring on which spring-natured plating is conducted. If a conductive material more elastic than the gold wiring is used as the core wiring, the spring-natured plating need not be conducted. Although an S-shape is exemplified as the flexible shape in FIG. 6, any shape may be employed such as a Z- , horizontal U- , or coil-shape as far as it may be subject to flexure.

This configuration also gives almost the same effects as those by the anisotropic conductive sheet 8.

Although in the above-mentioned embodiment the anisotropic conductive sheets 8 and 8A and the metal wiring material 8B have been arranged between the testing board K and the through electrodes 5, any other construction may be employed as far as at least it has conductivity and spring-nature.

### Second Embodiment

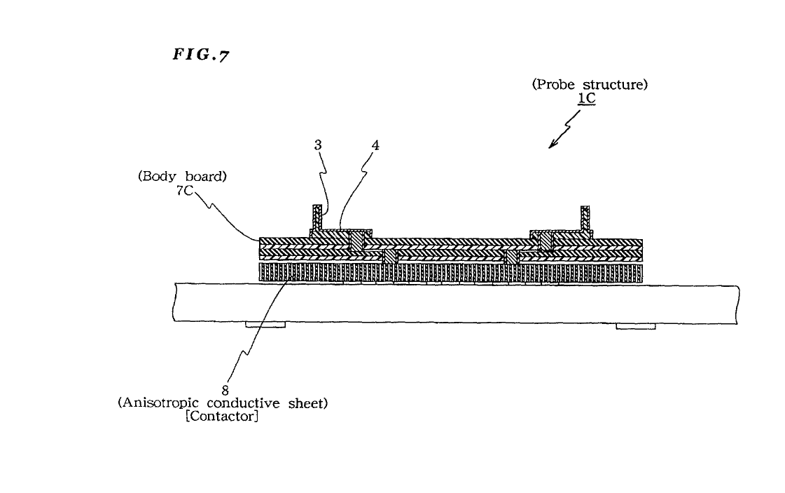

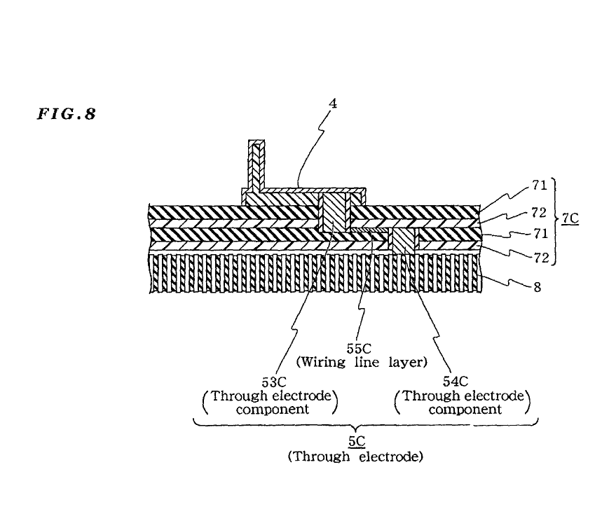

The following will describe a second embodiment of the invention with reference to FIGS. 7 and 8. FIG. 7 shows a cross-sectional view of a probe structure IC according to the second embodiment of the invention: The probe structure 1c shown in the figure features that a body structure 7C has a multi-layered construction and also that each of through electrodes 5C is comprised of conductive through electrode components 53C and 54C formed through the respective layers of the base substrate 7C, and a wiring 55C intervening between the layers for providing conduction between the through electrodes structures 53C. The other components are the same as those of the probe structure 1 and so omitted in description here.

As shown in FIG. 7, the base substrate 7C has a double-layer construction in which its upper and lower layers consist of insulating layers 71 and 72 respectively in a combined configuration. Note here that the number of the layers of this construction may be more than two.

The first through electrode component 53C of the through electrode 5C is formed through the upper layer of the base substrate 7C and the second through electrode component 54C, through the lower layer of the base substrate 7C. Further, the wiring layer 55C is formed between the upper and lower layers of the base substrate 7C in such a manner as to connect the lower end of the first through electrode component 53C to the upper end of the second through electrode component 54C. The wiring layer 55C is insulated against the overlying silicon layer 72, which is not shown though.

In such a configuration, the external terminal C1 of the semiconductor device C is electrically connected with the electrode K1 of the testing board K through the probe pin 3, the rewiring layer 4, the first through electrode component 53C, the wiring layer 55C, the second through electrode component 54C, and the anisotropic conductive sheet 8 in this order.

By this configuration, it is possible to give almost the same effects as those by the probe structure 1 and also to further expand the inter-electrode pitch of the testing board with respect to a pitch of the probe pins 3. If the base substrate is further multi-layered to result in a larger number of the through electrode components and the wiring layers being formed and a larger offset being given between each probe pin 3 and each through electrode 5, the space between the base substrate and the anisotropic conductive sheet and that between the anisotropic conductive sheet and the testing board K may be vacuumized (or depressurized) in order to provide pressing contact between the contactor 8 and the testing board K.

According to the invention, the through electrode is formed through the base substrate, so that in contrast to the prior art embodiment, it is unnecessary to wire the base substrate up to its outer periphery, thus enabling shortening the wiring. Therefore, a signal delay can be avoided effectively to accommodate high-speed testing. Also, in contrast to the prior art embodiment, it is unnecessary to provide a configuration comprised of a metal needle and a blocking plate, thus enabling avoiding a decrease in productivity caused by necessity to assemble these.

Also, the through electrode and the rewiring layer can be combined to enhance the degree of freedom in arrangement of the through electrodes with respect to the corresponding probe pins and also, the inter-through electrode pitch can be set arbitrarily even for a small pitch of the probe pins. This eliminates the necessity to arrange wirings in a radial manner from a group of the probe pins disposed at the center of the board in contrast to the prior art embodiment, thus enabling downsizing the probe structure.

Also, the probe pin can be comprised of a silicon-made core and a conductive film formed thereon to enable practical utilization of silicon whisker growing technologies and plating technologies, thus downsizing the probe pin and narrowing the pitch.

Further, in an aspect in which a contactor having elasticity and conductivity is mounted on the other side of the base substrate, when a semiconductor device to be tested is pressed against the probe pin for contact therewith, the contactor is deformed due to its own elasticity to thereby relax the occurrence of the deformation of the probe pin. Therefore, it is possible to effectively avoid deterioration of the probe pin due to its damage and deformation. Also, since the contactor can be deformed, it is possible to effectively accommodate irregularities in height of the electrodes caused by flexure of the testing board, thus electrically interconnecting the through electrodes and the corresponding electrodes effectively.

Thus, by the invention, it is possible to provide a probe structure and method for manufacturing the same which is superior to the prior art embodiment.

The invention may be embodied in other specific forms without departing from the spirit or essential characteristic thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No.2000-330523 (Filed on Oct. 30th, 2000) including specification, claims, drawings and summary are incorporated herein by reference in its entirety.

What is claimed is:

1. A probe structure for electrically contacting a semiconductor device and a testing board with each other, comprising:
a base substrate used with one side thereof as faced to said semiconductor device and the other side thereof as faced to said testing board;
a plurality of probe pins provided on said one side of said base substrate at positions corresponding to a plurality of external terminals of said semiconductor device respectively;
a plurality of through electrodes individually provided corresponding to a plurality of electrodes of said testing board; and
rewiring layers for individually connecting said probe pins and said through electrodes respectively on said one side of said base substrate, wherein:
said probe pins are each comprised of a silicon-made core and a conductive film formed thereon; and
said through electrodes each pass through said base substrate from one side to the other thereof and have a pitch as exposed on said the other side of said base substrate set larger than a pitch of said probe pins.

2. The probe structure according to claim 1, further comprising an elastic contactor positioned on said the other side of said base substrate, for providing individual conduction between each of said through electrodes and each of said electrodes of said testing board.

3. The probe structure according to claim 2, wherein said contactor is made of an elastic sheet material in which a great number of metal fine wirings are buried therethrough.

4. The probe structure according to claim 3, wherein said metal fine wirings are each buried perpendicular to a surface of said sheet material.

5. The probe structure according to claim 3, wherein said metal fine wirings are somewhat inclined with respect to perpendicular direction of said surface of said sheet material.

6. The probe structure according to claim 2, wherein said contactor is individually provided at an end of each of said through electrodes exposed from said the other side of said base substrate and made of a metal wiring material which is elastic and also which is so shaped as to be flexed arbitrarily.

7. The probe structure according to claim 2, wherein said contactor is individually provided at an end of each of said through electrodes exposed from said the other side of said base substrate and made of a wiring material which is comprised of an elastic core material and a reinforcing material for coating said core material to add elasticity and also which is so shaped as to be flexed arbitrarily.

8. The probe structure according to claim 1, wherein:
said base substrate has a multi-layer construction; and
said through electrodes are each comprised of a conductive through electrode component formed through each layer of said base substrate and a wiring layer intervening between said layers for providing conduction between said through electrode components.

9. The probe structure according to claim 2, wherein:
said base substrate has a multi-layer construction; and
said through electrodes are each comprised of a conductive through electrode component formed through each layer of said base substrate and a wiring layer intervening between said layers for providing conduction between said through electrode components.

10. The probe structure according to claim 3, wherein:
said base substrate has a multi-layer construction; and
said through electrodes are each comprised of a conductive through electrode component formed through each layer of said base substrate and a wiring layer intervening between said layers for providing conduction between said through electrode components.

11. The probe structure according to claim 4, wherein:
said base substrate has a multi-layer construction; and
said through electrodes are each comprised of a conductive through electrode component formed through each layer of said base substrate and a wiring layer intervening between said layers for providing conduction between said through electrode components.

12. The probe structure according to claim 5, wherein:
said base substrate has a multi-layer construction; and
said through electrodes are each comprised of a conductive through electrode component formed through each layer of said base substrate and a wiring layer intervening between said layers for providing conduction between said through electrode components.

13. The probe structure according to claim 6, wherein:
said base substrate has a multi-layer construction; and
said through electrodes are each comprised of a conductive through electrode component formed through each layer of said base substrate and a wiring layer intervening between said layers for providing conduction between said through electrode components.

14. The probe structure according to claim 7, wherein:
said base substrate has a multi-layer construction; and
said through electrodes are each comprised of a conductive through electrode component formed through each layer of said base substrate and a wiring layer intervening between said layers for providing conduction between said through electrode components.

15. A method for manufacturing a probe structure for electrically contacting a semiconductor device and a testing board, comprising the steps of:
forming a plurality of through electrodes in a predetermined base substrate from one side to the other thereof as arranged corresponding to electrodes of said testing board;
forming a rewiring layer which is provided on one side of said base substrate and also which provides individual conduction to each of said through electrodes from each position corresponding to each of a plurality of external terminals of said semiconductor device; and
forming a probe pin which is provided on said one side of said base substrate and also which contacts each of said external terminal to each position corresponding to each of said plurality of external terminals of said semiconductor device, wherein;
said step of forming said through electrodes includes a step of forming a plurality of holes as arranged corresponding to said electrodes of said testing board of said base substrate to fill said holes with a conductive material; and
said step of forming said probe pin includes a step of growing a silicon-made whisker at each position corresponding to each of said plurality of external terminals of said semiconductor device to then form a conductive film on each of said silicon-made whiskers.
